(19) United States
(12) Patent Application Publication
(10) Pub. No.: US 2003/0116817 A1
(43) Pub. Date: Jun. 26, 2003

(54) Image sensor structure

(76) Inventors: Nai Hua Yeh, Hsinchu Hsien (TW); Chen Pin Peng, Hsinchu Hsien (TW); Jason Chuang, Hsinchu Hsien (TW); Hsiu Wen Tu, Hsinchu Hsien (TW); Kuang Yu Fan, Hsinchu Hsien (TW); Mon Nan Ho, Hsinchu Hsien (TW); Fu Yung Huang, Hsinchu Hsien (TW); Meng Ru Tsai, Hsinchu Hsien (TW); Allis Chen, Hsinchu Hsien (TW); Chih Hsien Chung, Hsinchu Hsien (TW); Chih Cheng Hsu, Hsinchu Hsien (TW); Yung Sheng Chiu, Hsinchu Hsien (TW)

Correspondence Address: PRO-TECHTOR INTERNATIONAL, 20775 Norada Court, Saratoga, CA, 95070-3018, US

(21) Appl. No.: 10/027,537

(22) Filed: Dec. 20, 2001

(51) Int. Cl. H01L 31/00

(52) U.S. Cl. 257/444

(57) ABSTRACT

The image sensor structure of the invention is used for electrically connecting to a printed circuit board. The image sensor structure includes a substrate, a projecting layer, an image sensing chip, a plurality of wires, and a transparent layer. The substrate has a first surface and a second surface. The first surface is formed with signal output terminals for electrically connecting to the printed circuit board. The projecting layer has an upper surface and a lower surface. The lower surface is adhered to the second surface of the substrate to form a cavity with the substrate. The upper surface is formed with signal input terminals. The image sensing chip is placed within the cavity formed by the substrate and the projecting layer, and is adhered onto the second surface of the substrate. The plurality of wires each has a first terminal and a second terminal. The first terminals are electrically connected to the image sensing chip. The second terminals are electrically connected to the signal input terminals of the upper surface of the projecting layer. The transparent layer is placed on the upper surface of the projecting layer. According to the invention, the package volume of the image sensor can be reduced so as to facilitate the manufacturing of the package.

### BACKGROUND OF THE INVENTION

1. Field of the Invention

The invention relates to an image sensor structure, in particular, to an image sensor capable of reducing the size of the image sensor package by changing the wire-bonding path.

2. Description of the Related Art

Referring to FIG. 1, an conventional image sensor includes a substrate 10, a projecting layer 18, an image sensing chip 26, a plurality of wires 28, and a transparent layer 34. The substrate 10 has a first surface 12 and a second surface 14. A plurality of signal output terminals 15 are formed on the first surface 12 for electrically connecting to a printed circuit board (not shown). A plurality of signal input terminals 16 are formed on the second surface 14. The projecting layer 18 has an upper surface 20 and a lower surface 22. The lower surface 22 is adhered to the second surface 14 of the substrate 10 to form a cavity 24 with the substrate 10. The image sensing chip 26 is placed within the cavity 24 fromed by the substrate 10 and the projecting layer 18. Each of the plurality of wires 28 has a first terminal 30 and a second terminal 32. The first terminal 30 is used for electrically connecting to the image sensing chip 26, while the second terminal 32 is used for electrically connecting to the signal input terminal 16 of the substrate 10. The transparent layer 34 is placed on the upper surface 20 of the projecting layer 18.

Accordingly, when the image sensing chip 26 has a large scale, it is inconvinient, or even impossible, in the manufacturing processes for bonding and electrically connecting the plurality of wires 28 to the signal input terminals 16 of the substrate 10. Therefore, the size of the substrate 10 has to be enlarged so as to increase the space for wire bonding. Accordingly, the whole package volume of the image sensing chip is further enlarged, thereby causing inconvinent usage.

### SUMMARY OF THE INVENTION

It is therefore an object of the invention to provide an image sensor structure that is easy to be packaged and capable of reducing the package volume and the manufacturing costs.

Another object of the invention is to provide an image sensor structure capable of packaging image sensing chips having different sizes without changing the package volume. The object of producing packages having the same volume can be achieved.

To achieve the above-mentioned object, the image sensor structure of the invention is used for electrically connecting to a printed circuit board. The image sensor structure includes a substrate, a projecting layer, an image sensing chip, a plurality of wires, and a transparent layer. The substrate has a first surface and a second surface. The first surface is formed with signal output terminals for electrically connecting to the printed circuit board. The projecting layer has an upper surface and a lower surface. The lower surface is adhered to the second surface of the substrate to form a cavity with the substrate. The upper surface is formed with signal input terminals. The image sensing chip is placed within the cavity formed by the substrate and the projecting layer, and is adhered onto the second surface of the substrate. The plurality of wires each has a first terminal and a second terminal. The first terminals are electrically connected to the image sensing chip. The second terminals are electrically connected to the signal input terminals of the upper surface of the projecting layer. The transparent layer is placed on the upper surface of the projecting layer. According to the invention, the package volume of the image sensor can be reduced so as to facilitate the manufacturing of the package.

### BRIEF DESCRIPTION OF THE DRAWINGS

These and other objects and advantages of the present invention will become apparent by reference to the following description and accompanying drawings wherein:

FIG. 1 is a cross-sectional view showing a conventional image sensor;

FIG. 2 is a schematic illustration showing an image sensor of the invention; and

FIG. 3 is a cross-sectional view showing an image sensor of the invention.

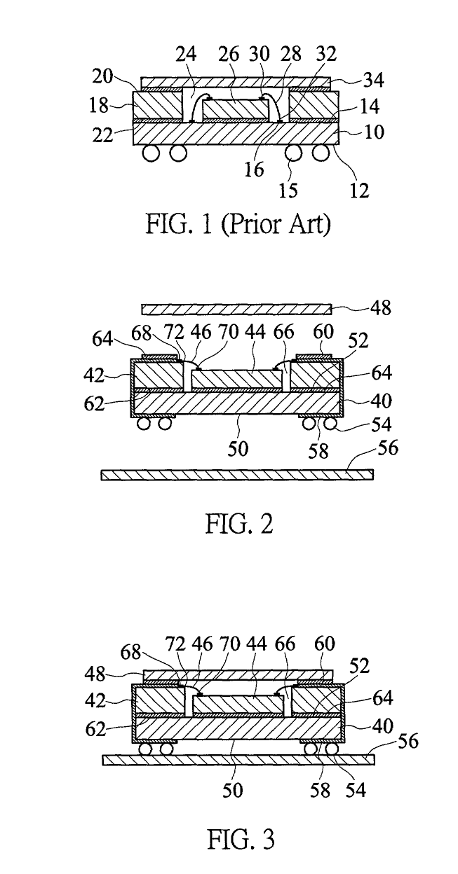

### DETAIL DESCRIPTION OF THE INVENTION

Referring to FIGS. 2 and 3, the image sensor structure of the invention includes a substrate 40, a projecting layer 42, an image sensing chip 44, a plurality of wires 46 and a transparent layer 48.

The substrate 40 has a first surface 50 and a second surface 52. Signal output terminals 58 are formed on the first surface 50 and formed with metallic balls 54 for electrically connecting to the printed circuit board 56.

The projecting layer 42 has an upper surface 60 and a lower surface 62. The lower surface 62 is adhered onto the second surface 52 of the substrate 40 by an adhesive layer 64, so as to form a cavity 66 with the substrate 40. A part of the upper surface 60 is coated with the adhesive layer 64 for adhering to the transparent layer 48. Signal input terminals 68 are formed on another part of the upper surface 60 without the adhesive layer, and are electrically connected to the signal output terminals 58 of the lower surface 62 via the sides of the projecting layer 42.

The image sensing chip 44 is placed within the cavity 66 formed by the substrate 40 and the projecting layer 42, and is adhered to the second surface 52 of the substrate 40.

Each of the plurality of wires 46 has a first terminal 70 and a second terminal 72. The first terminals 70 are electrically connected to the image sensing chip 44. The second terminals 72 are electrically connected to the signal input terminal 68 on the upper surface 60 of the projecting layer 42. The transparent layer 48 located on the upper surface 60 of the projecting layer 42 is a transparent glass plate for receiving optical signals.

In assembly, the image sensing chip 44 is firstly adhered onto the second surface 52 of the substrate 40. Then, the first terminals 70 of the the plurality of wires 46 are bonded onto the image sensing chip 44 while the second terminals 72 are bonded onto the signal input terminals 68 of the upper surface 60 of the projecting layer 42. Next, the transparent layer 48 is adhered to the upper surface 60 of the projecting layer 42. Thus, the package of the image sensing chip is completed.

Accordingly, since the plurality of wires 46 are electrically connected to the signal input terminals 68 of the upper surface 60 of the projecting layer 42 without occupying any surface of the cavity 66, the size of the cavity 66 formed by the projecting layer 42 and the substrate 40 for receiving the image sensing chip 44 may be close to the size of the image sensing chip 44. That is, it is possible to select the substrate 40 having a smaller size to package the image sensing chip 44 having the same original size. Thus, it is possible to obtain an image sensor package having smaller volume and to decrease the material costs for the substrate 40.

Furthermore, image sensing chips, having different sizes ranging from a smaller size to a size close to that of the image sensing chip, can be respectively placed into the cavity 66 on the same substrate 40. Thus, the substrate 40 is suitable for the packages of image sensing chips 44 having different sizes, thereby facilitating the material purchasement.

In addition, the method for wire-bonding the plurality of wires 46 onto the upper surface 60 of the projecting layer 42 is more convenient than that for wire-bonding the wires onto the substrate 40. Thus, the manufacturing costs can be decreased and the yield can be increased.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor structure for electrically connecting to a printed circuit board, the image sensor structure comprising:
a substrate having a first surface and a second surface, the first surface being formed with signal output terminals for electrically connecting to the printed circuit board;
a projecting layer having an upper surface and a lower surface, the lower surface being adhered to the second surface of the substrate to form a cavity with the substrate, and the upper surface being formed with signal input terminals;
an image sensing chip placed within the cavity formed by the substrate and the projecting layer, and adhered onto the second surface of the substrate;
a plurality of wires each of which having a first terminal and a second terminal, the first terminals being electrically connected to the image sensing chip, and the second terminals being electrically connected to the signal input terminals of the upper surface of the projecting layer; and
a transparent layer placed on the upper surface of the projecting layer.

2. The image sensor structure according to claim 1, wherein a part of the upper surface of the projecting layer is coated with an adhesive layer for adhering to the transparent layer, and the other part of the upper surface without the adhesive layer is formed with the signal input terminals for electrically connecting to the second terminals of the plurality of wires.

3. The image sensor structure according to claim 1, wherein the transparent layer is transparent glass.

4. The image sensor structure according to claim 1, wherein the signal output terminals of the first surface of the substrate are electrically connected to metallic balls for electrically connecting to the printed circuit board.

5. The image sensor structure according to claim 1, wherein the signal input terminals of the upper surface of the projecting layer are electrically connected to the signal output terminals of the first surface of the substrate via sides of the projecting layer and the substrate.
